(19) United States
(12) Patent Application Publication
(10) Pub. No.: US 2003/0009721 A1
(43) Pub. Date: Jan. 9, 2003

(54) Method and system for background ECC scrubbing for a memory array

(75) Inventors: Louis L. Hsu, Fishkill, NY (US); Li-Kong Wang, Montvale, NJ (US); Tin-Chee Lo, Fishkill, NY (US); Chorng-Lii Hwang, Wappingers Falls, NY (US)

Correspondence Address: Paul J. Farrell, Esq., DILLWORTH & BARRESE, LLP, 333 Earle Ovington Blvd., Uniondale, NY, 11553, US

(73) Assignee: INTERNATIONAL BUSINESS MACHINES CORPORATION, Armonk, NY

(21) Appl. No.: 09/900,303

(22) Filed: Jul. 6, 2001

(51) Int. Cl. G11C 29/00

(52) U.S. Cl. 714/773

(57) ABSTRACT

A method and system for background ECC scrubbing, i.e., checking and correcting scheme, for a memory array are provided which do not affect normal system operation of the memory array and do not add additional time delay to the data flow path, especially a data output flow path. Unlike the prior art, an ECC decoder circuit block is placed outside a critical data output path of a memory array. A data refresh path is provided to periodically pull the data out from the memory array via the ECC decoder circuit block for checking and correcting the data. The outgoing data in response to a read command does not suffer any time delay caused by the ECC checking and correcting scheme, since the data are not read out via the ECC decoder circuit block. Any hard errors are corrected by at least one redundancy circuit.

### FIELD OF THE INVENTION

The present invention relates to integrated circuit design, and more specifically, to a method and system for background error correction code (ECC) scrubbing, i.e., checking and correcting, for a memory array.

### BACKGROUND OF THE INVENTION

The implementation of redundancy circuits into integrated circuit (IC) systems has proven to significantly improve chip reliability. The use of error-detecting and error correction codes, such as parity and ECC's, in combination with redundancy circuits has improved the reliability of chips even further.

A chip's reliability is affected due to fabrication defects and alpha particle irradiation during chip operation. For example, in a memory chip, if the critical charge (also known as Qcrit) of a memory cell is not sufficient, the stored state can be altered by alpha particle irradiation. By employing an error tolerable circuit, such as an ECC circuit, hard errors caused by fabrication defects can typically be corrected, and also soft errors caused, for example, by the insufficient cell critical charge during chip operation can be corrected. In other words, memory chips become more tolerant against errors and faults with the implementation of ECC circuits.

Different on-chip ECC schemes have been employed on memory chips, such as DRAM and SRAM chips. In a typical ECC design, as shown in FIG. 1, a first portion 12A of an ECC circuit 12 is used to create check bits for incoming data, Data_in, prior to writing the data into a memory array 11 during a write operation. When reading the data out, Data_out, of the memory array 11, the data bits and the check bits are both retrieved. The data bits are tested by a second portion 12B of the ECC circuit 12 using the check bits and syndrome bits which are generated to indicate which data bits are faulty. The ECC circuit 12 uses the syndrome bits to correct the faulty bits.

The advantage of using an ECC scheme is to enhance the ability to correct random cell bit failures during chip operation and to increase chip yield during fabrication. The cost, however, is not only that it adds hardware overhead (5 to 25% depending on the memory to chip size ratio), but also adds extra time delay in the data flow path. For example, when a small memory array is used for high-speed applications, for example, on-chip L1 and L2 caches, fuse information storage, and address directory storage, the chip size may not be a primary concern. However, the delay in the data flow path caused by the addition of an ECC circuit is generally not acceptable, since the delay is typically not within the chip's specifications or not application tolerant.

In addition to the added time delay of prior art ECC schemes, an additional concern is how to perform a memory refresh operation in the presence of an ECC circuit without affecting the stored check bits. One prior art solution is shown in FIG. 2. The solution entails using one port of an ECC circuit 13 for receiving incoming data, Data_in, during a write operation via an ECC encoder circuit 14. The data are passed through the ECC encoder circuit 14 to create check bits as described above. Both the incoming data and the corresponding check bits are stored in the memory array 11.

Another port is used for retrieving and reading out data, Data_out, from the memory array 11 during a read operation. The data is passed through an ECC decoder circuit 15 of the ECC circuit 13 to check and correct for errors. During a memory refresh operation, the data stored in the memory array 11 are refreshed via the same port used for reading out the data, thereby protecting the integrity of the stored check bits. Nonetheless, the ECC decoder circuit 15 is in the Data_out critical path which can affect the performance of data buffers during normal array operation, since the error check and correcting step causes a significant delay in the data flow path.

### SUMMARY

Accordingly, it is an aspect of the present invention to provide a method and system for background error correction code (ECC) scrubbing, i.e., checking and correcting, for a memory array which do not affect normal system operation of the array and do not add additional time delay to the data flow path.

Another aspect of the present invention is to provide a background error correction code data integrity checking scheme for a single-port memory array system.

Finally, another aspect of the present invention is to provide a background error correction code data integrity checking scheme for a dual-port memory array system.

Accordingly, the present invention provides a method and system for background ECC scrubbing, i.e., checking and correcting scheme, for a memory array which do not affect normal system operation of the memory array and do not add additional time delay to the data flow path, especially a data output flow path. The present invention does not have an ECC decoder circuit block in a critical data output path of the memory array. The ECC decoder circuit block is placed outside the data output path. A data refresh path is provided to periodically pull the data out from the memory array via the ECC decoder circuit block for checking and correcting the data. The outgoing data in response to a read command does not suffer any time delay caused by the ECC checking and correcting scheme, since the data are not read out via the ECC decoder circuit block. Any hard errors are corrected by at least one redundancy circuit.

### BRIEF DESCRIPTION OF THE FIGURES

FIG. 1 is a block diagram of a prior art error correction code (ECC) scheme;

FIG. 2 is a block diagram illustrating a prior art dual-port DRAM array system having an ECC scheme;

FIG. 3 is a block diagram illustrating an ECC checking and correcting scheme in accordance with the present invention;

FIG. 4A is a block diagram illustrating a single-port memory array system having a background ECC scrubbing scheme in accordance with the present invention;

FIG. 4B is a block diagram of a two-bit state (shift) register for the single-port memory array system of FIG. 4A;

FIG. 5A is a block diagram illustrating a dual-port memory array system having a background ECC scrubbing scheme in accordance with the present invention; and

FIG. 5B is a block diagram of a two-bit state (shift) register for the dual-port memory array system of FIG. 5A.

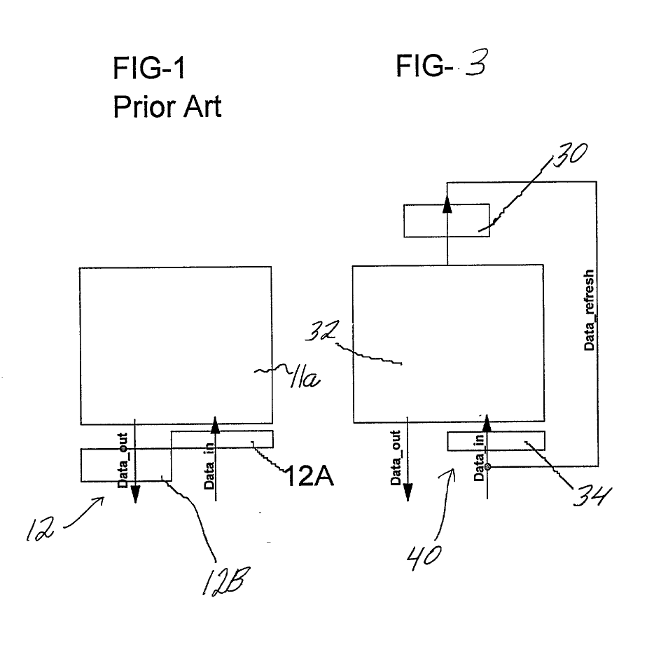

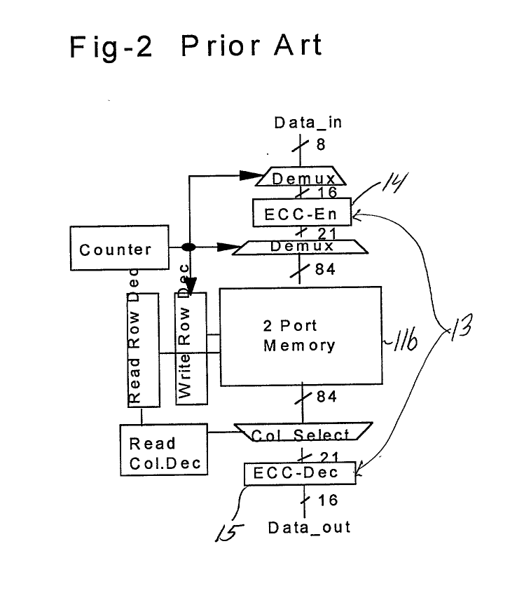

### DETAILED DESCRIPTION OF THE INVENTION

With reference to FIG. 3, there is shown a background ECC scrubbing or error code correction (ECC) checking and correcting scheme for a memory array in accordance with the present invention. The ECC scheme does not affect normal system operation of the memory array and does not add additional time delay to a data flow path, especially a data output flow path. In contrast to the prior art, the ECC scheme in accordance with the present invention does not have an ECC decoder circuit block in a critical data output path of the memory array.

As illustrated by FIG. 3, the present invention provides an ECC decoder circuit block 30 of an ECC circuit 40 placed outside a data output path, Data_out. A data refresh path, Data_refresh, is provided to periodically pull the data out from a memory array 32 via the ECC decoder circuit block 30 for checking and correcting the data.

If the memory array 32 is a single-port memory array as in the first embodiment described below, the memory array 32 is accessed during an idle mode, i.e., when the memory array 32 is not being accessed for performing read and write operations, for pulling the data out for ECC data scrubbing or refreshing according to the present invention. If the memory array 32 is a dual-port memory array, i.e., the memory array 32 includes a first and a second port, as in the second embodiment described below, the Data_refresh path accesses the memory array 32 via the first port for performing data scrubbing or refreshing, and the second port is used for simultaneously accessing the memory array 32 for performing read and write operations.

The outgoing data in response to a read command does not suffer any time delay caused by the ECC checking and correcting scheme, since the data are not read out via the ECC decoder circuit block 30. Any hard errors are corrected by at least one redundancy circuit. Refreshed data and new data, i.e., incoming data, Data_in, are written into the memory array 32 via an ECC encoder circuit block 34 of the ECC circuit 40.

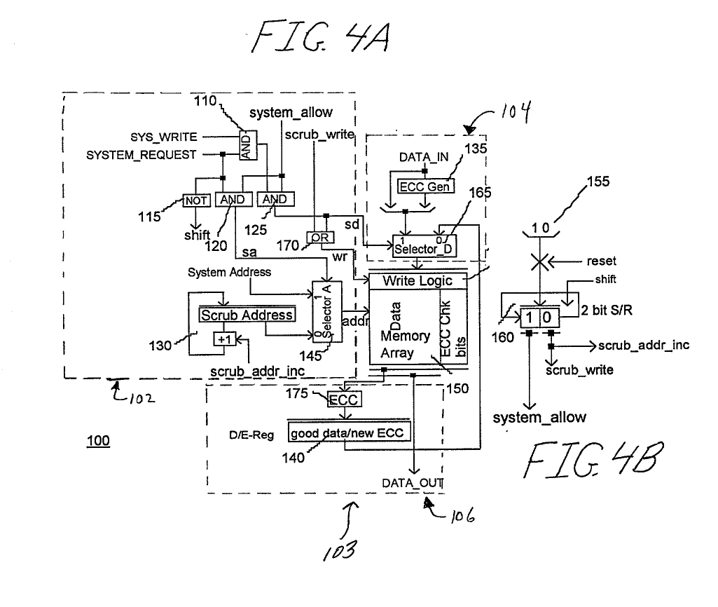

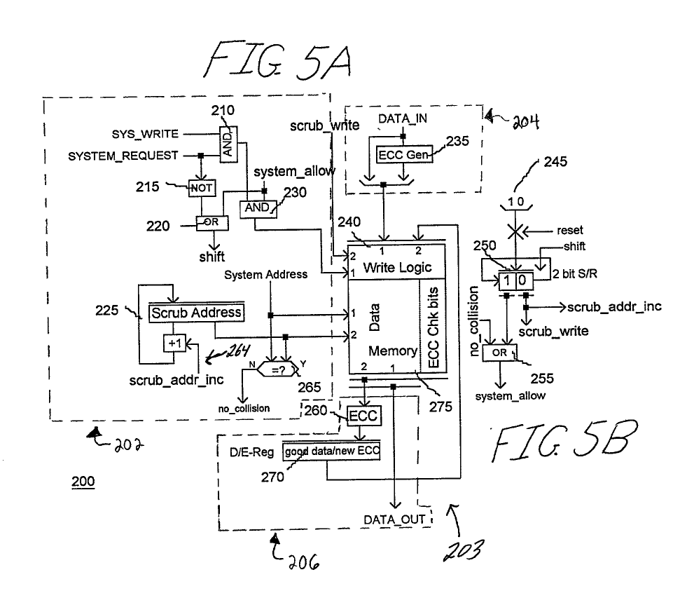

Three embodiments of the ECC checking and correcting scheme are described hereinbelow with reference to FIGS. 4A-5B. The first embodiment, as noted above, is directed to a single-port memory array system having a background ECC scrubbing scheme in accordance with the present invention. The second embodiment, as noted above, is directed to a dual-port memory array system having a background ECC scrubbing scheme in accordance with the present invention. Both embodiments include a two-bit state (shift) register for controlling the background ECC scrubbing scheme. The third embodiment is a combination of the first and second embodiments.

First Embodiment: Single-Port Memory Background ECC Scrubbing

The background ECC scrubbing or ECC checking and correcting scheme can apply to almost any memory array, however, for simplicity of illustration, an SRAM will be employed in describing the first embodiment illustrated by FIG. 4A. Referring to FIG. 4A, there is shown a background ECC scrubbing system 100 having a control circuit block 102 and a memory circuit block 103. The control circuit block 102 includes at least three AND gates, 110, 120 and 125, one NOT gate 115, i.e., an inverter, one OR gate 170, one MUX (or Selector_A) 145 and one Scrub address generator 130.

The memory circuit block 103 includes a data_in block 104, a single-port memory array 150 and data_out block 106. The memory array 150 stores write logic and ECC check bits. The data_in block 104 includes an ECC generator 135 (similar to the ECC encoder circuit block described above) and a MUX (or Selector_D) 165. The ECC generator 135 checks the data transmitted via the data_in path and generates ECC check bits which are stored in the memory array 150. The data_out block 106 includes an ECC decoder circuit block 175 and ECC checked register 140 (also known as D/E Reg).

With reference to FIG. 4B, background ECC scrubbing is controlled by a two-bit state (shift) register 160 in which a ‘1’ is continuously circulated under a control signal “shift”. The control signal “shift” is high in the absence of any system access request. During system reset, the state value “10” is loaded into the two-bit register.

The shift signal is generated by the NOT gate 115 when SYSTEM_REQUEST is “low”, or when the system is not requested by a processor, such as a CPU. At this moment, the memory array 150 starts its internal data srubbing process. In other words, background data scrubbing according to the present invention is not controlled by the processor. Background data scrubbing is performed automatically when the system is on but and no operations, such as memory write and read operations, are requested by the processor. Accordingly, data maintenance is performed by the system 100 whenever the memory array 150 is not being accessed for performing operations under the control of the processor.

When the ‘1’ is in the most significant bit (or the leftmost bit), the SRAM is in read mode. When the ‘1’ is in the least significant bit (LSB or the rightmost bit), the SRAM is in write mode characterized by signal ‘wr’ being high.

When there is no system access to the SRAM, the SYSTEM_REQUEST signal is low, and in turn, the output of the two AND gates 120 and 125 is low. (Signals “sa” and “sd” are both low or ‘0’.) At this moment, the SRAM takes the Scrub Address, generated by the scrub address generator 130, because the control signal “sa” to the Selector_A 145 is ‘0’. Data and ECC check bits are read out from the memory array 150 and undergo ECC correction. The good data and associated good check bits are stored in the register D/E-Reg 140.

Now, the ‘1’ is shifted rightward to the least significant bit of the state register 160 and the “scrub_write” signal is generated. The content of D/E-Reg 140 is written back into the same location in the memory array 150 under the control of “sd”, which is the control signal to the Selector_D 165. At this point, “sd” is low and “wr” is high, since the “scrub_write’ signal is high. The Scrub Address is also incremented by way of the control signal “scrub_addr_inc” in preparation of the scrubbing of the contents of the next address. That is, since the least significant bit of the two-bit shift register 160 is “1”, the scrub address is incremented to allow the system 100 to select next wordline of the memory array 150 for data scrubbing. The scrub Read/Write process is repeated continuously until the SYSTEM_REQUEST is asserted.

When the requester (e.g., a CPU) needs to access the SRAM, it raises the SYSTEM_REQUEST signal. If the state register 160 is in a “01” state, the “system_allow” signal is low which means “scrub-write” is underway and the request will be on-hold for the present cycle. Note that “sa” and “sd”, the control signals to the Selector_A 145 and Selector_D 165, are both low and the write signal “wr” of the SRAM is high. In the next cycle, the content of the state register 160 becomes “10” which results in gating the SYSTEM_REQUEST signal into “sa” causing the SRAM to take the system address. At the same time, the “shift” signal is low and the two-bit state register 160 ceases to shift and is maintained in the “10” state until the SYSTEM_REQUEST signal is removed. The scrub address generator 130 will keep pointing to the last scrubbed address until the next scrubbing cycle takes place. The following examples illustrate the data flow during a Read or Write request:

(1) Read Request: This is characterized by SYS WRITE signal being low which causes the “wr” signal to be unasserted or ‘0’. The SRAM array is read and raw data is delivered to the requester without going through the time consuming ECC decoding circuitry 175.

(2) Write Request: This is the case when SYS_WRITE is high. In this mode, it is easy to see that “sa”, “sd” and “wr” are all high, thereby allowing the requester to send DATA_IN together with its newly generated ECC check bits into the SRAM memory array 150.

Second Embodiment: Dual-Port Memory Background ECC Scrubbing

Referring to FIG. 5A, there is shown a dual-port ECC scrubbing system 200 according to the present invention having a control circuit block 202 which is slightly different from that of a single-port system, such as the system 100 described above with reference to FIGS. 4A and 4B. The control circuit block 202 of the dual-port background ECC scrubbing system 200 includes at least two AND gates 210 and 230, one NOT gate 215, i.e., an inverter, one OR gate 220, and a scrub address generator 225. The scrub address generator 225 includes an address increment circuit 264 and a comparator 265 to detect address collisions.

Similar to the first embodiment, a memory circuit block 203 is provided having a data_in block 204, a dual-port memory array 275, and data_out block 206. The data_in block 204 includes an ECC generator 235 (similar to the ECC encoder circuit block described above). The data_out block 206 includes an ECC decoder 260 and ECC checked register 270 (also known as D/E Reg). The ECC generator 235 checks the data transmitted via the data₁₃ in path and generates ECC check bits. The memory array 275 stores write logic and the ECC check bits.

With reference to FIG. 5B, background ECC scrubbing is controlled by a two-bit state (shift) register 250 in which a ‘1’ is continuously circulated under a control signal “shift” which is high in the absence of any system access request. During system reset, the state value “10”, as referenced by reference numeral 245, is loaded into the two-bit register 250. When the ‘1’ is in the most significant bit (or leftmost bit), the SRAM memory array 275 is in read mode. An “OR” gate 255 is inserted to avoid array collision problems which will be described below. When the ‘1’ is in the least significant bit (LSB or the rightmost bit), the SRAM memory array 275 is in write mode characterized by signal ‘wr’ being high.

In general, for a dual-port SRAM, the first port is designated for normal access, while the second port is used for ECC scrubbing. Only when a collision occurs, that is, when a CPU accesses the same wordline address while performing ECC scrubbing, does the system 200 forbid normal access. At this moment, “system_allow” is low. As long as there is no address collision situation and the “system_allow” signal is high, does normal system operation occur. The SYSTEM_REQUEST signal has no effect on the ECC scrubbing operation, since ECC scrubbing has a higher priority. When the incoming system address is different from the current scrub address, a “no_collision” signal is generated from the comparator 265. This “no_collision” signal will enable the “system₁₃ allow” signal from the OR gate 255. The “system_allow” signal allows the system to simultaneously perform normal access and background ECC scrubbing via ports one and two, respectively.

During background ECC scrubbing, data and ECC check bits are read out from the second port of the SRAM memory array 275 and undergo ECC correction via the ECC decoder circuit block 260. The good data and associated good check bits are stored in the register D/E-Reg 270. Then, the ‘1’ is shifted rightward to the LSB of the state register and the “scrub_write” signal is generated. The contents of D/E-Reg 270 is written back into the same location in the SRAM memory array 275 via the second port. At this point, Scrub Address is incremented by way of the control signal “scrub_addr_inc” in preparation of the scrubbing of the next address. The scrub Read/Write process is repeated continuously regardless if the SYSTEM_REQUEST is asserted.

When the requester (e.g., a CPU) needs to access the SRAM, it raises the SYSTEM_REQUEST signal. First, the system address is compared to the current scrub address for checking collision. If no collision is detected, normal array access is allowed. Otherwise, it will check whether the “system_allow” signal to determine whether array access is allowed. If the “system_allow” signal is negative, then array access is on-hold until the “system_allow” signal is positive. Note that the system 200 does not allow normal system access when the “scrub_write” operation is on-going. The penalty of cache access is therefore very minimal.

Third Embodiment: Dual-Port Memory Background ECC Scrubbing

As a further embodiment, the background ECC scrubbing scheme can further be modified to allow a memory system to access a cache via a dual-port memory array while one port is designated for ECC scrubbing. The modification is a combination of the first and the second embodiments where the first embodiment is applied to the second port of the memory array for simultaneous normal access and scrub operations.

For example, the first port of the memory array can be dedicated for normal operation as well as ECC data scrubbing or refreshing, while the second port of the memory array is used only for normal data scrubbing. In this case, ECC data scrubbing can be done at any period of time, regardless if the memory array is requested by a system processor or not. Accordingly, the memory array will experience almost no interruption by the ECC operation.

The operation of the individual blocks and components are the same as described above for the first and second embodiments, and therefore, their operation will not be described in detail with reference to this embodiment.

The present invention provides a background ECC scrubbing scheme for a memory system, such as an embedded or stand-alone memory system. A control circuit block enables smooth and invisible ECC operations. The method of the present invention prevents soft-errors without suffering delay penalty by the ECC circuitry. Internal redundancy circuits can be used to replace hard-fail components due to hard errors.

What has been described herein is merely illustrative of the application of the principles of the present invention. For example, the functions described above and implemented as the best mode for operating the present invention are for illustration purposes only. Other arrangements and methods may be implemented by those skilled in the art without departing from the scope and spirit of this invention.

We claim:

1. An error correction code (ECC) checking and correcting system for a memory array, the system comprising:
means for writing data to the memory array via a data input path traversing an ECC circuit block for checking the integrity of the data; and
means for reading data stored within the memory array via a data output path, wherein the data output path does not traverse the ECC circuit block.

2. The system according to claim 1, further comprising means for refreshing data stored within the memory array via a refresh data path traversing an ECC decoder circuit block and an ECC encoder circuit block of the ECC circuit block.

3. The system according to claim 1, wherein the memory array is one of a single-port and a dual-port memory array configured for storing ECC check bits.

4. The system according to claim 2, wherein the means for refreshing is enabled when the memory array is in an idle mode.

5. The system according to claim 3, wherein the memory array includes a first and a second port, wherein the refresh data path accesses the memory array via the first port and the second port is used for accessing the memory array for performing read and write operations.

6. The system according to claim 2, further comprising control circuitry for controlling the means for refreshing.

7. The system according to claim 6, wherein the control circuitry comprises a shift register for outputting a control signal in accordance with a logic value of a bit stored within the shift register.

8. The system according to claim 7, wherein the control circuitry further comprises logic circuitry for receiving the control signal and at least one system signal for controlling background ECC checking and correcting.

9. The system according to claim 7, wherein the shift register is a two-bit shift register.

10. The system according to claim 9, wherein the two-bit shift register is connected to a logic OR gate and a comparator circuit via the OR gate for determining occurrence of address collisions.

11. The system according to claim 2, wherein the ECC encoder circuit block includes a generator for receiving data via the data input path and generating ECC check bits indicating the existence of any errors within the data.

12. The system according to claim 2, wherein the ECC decoder circuit block includes a register for storing non-faulty data and associated ECC check bits.

13. The system according to claim 12, further comprising at least one multiplexer for multiplexing data stored within the register into the memory array.

14. The system according to claim 6, wherein the control circuitry further includes an address incrementing circuit for incrementing a memory array address in response to a memory address incrementing signal.

15. The system according to claim 6, wherein the control circuitry further includes a multiplexer for multiplexing between a system address and a ECC checking and correcting address.

16. A method for error correction code (ECC) checking and correcting for a memory array, the method comprising the steps of:
writing data to the memory array via a data input path traversing an ECC circuit block for checking the integrity of the data; and
reading data stored within the memory array via a data output path which does not traverse the ECC circuit block.

17. The method according to claim 16, further comprising the step of refreshing data stored within the memory array via a refresh data path traversing an ECC decoder circuit block and an ECC encoder circuit block of the ECC circuit block.

18. The method according to claim 16, wherein the memory array is one of a single-port and a dual-port memory array configured for storing ECC check bits.

19. The method according to claim 17, further comprising the step of outputting a control signal to logic circuitry in accordance with a logic value of a bit stored within a shift register for controlling the refreshing step.

20. The method according to claim 19, wherein the shift register is a two-bit shift register.

21. The method according to claim 16, further comprising the step of determining an address collision occurrence between a system memory address and an ECC checking and correcting memory address.

22. The method according to claim 16, further comprising the step of checking the integrity of data transmitted via the data input path and generating ECC check bits indicating the existence of any errors within the data.

23. The method according to claim 16, further comprising the step of incrementing a memory array address in response to a memory array incrementing signal.
